(19) United States
(12) Patent Application Publication
(10) Pub. No.: US 2009/0128367 A1
(43) Pub. Date: May 21, 2009

(54) Sensing ball

(76) Inventors: Guoqi Zhang, Shenzhen (CN); Xianbin Song, Shenzhen (CN); Zheming Li, Shenzhen (CN)

Correspondence Address: JACOBSON HOLMAN PLLC, 400 SEVENTH STREET N.W., SUITE 600, WASHINGTON, DC, 20004, US

(21) Appl. No.: 12/068,286

(22) Filed: Feb. 5, 2008

(30) Foreign Application Priority Data
Nov. 16, 2007 (CN) 200710124575.4

(51) Int. Cl. H03K 17/94; H03M 11/00

(52) U.S. Cl. 341/20

(57) ABSTRACT

The present invention provides a sensing ball comprising a ball body on which several sensors are mounted, and in the ball body are mounted motors, an eccentric device driven by the motor and a controller for controlling rotation of the eccentric device, in which the sensors are connected to the controller. When a moving object approaches the sensing ball, the sensors generate sensing signals and input the sensing signals into the controller, and the controller controls rotation of the eccentric device and drives the ball body to roll back and forth in a specified direction or keeps it static based on the sensing signals. The sensing ball according to the present invention can realize a relatively strong interaction with a moving object, for example, when a child approaches the sensing ball, the sensing ball can move toward the direction far from the child, therefore stimulating his/her curiosity and attracting him/her to go ahead or creep so that the child may learn to walk and creep in this way.

### FIELD OF THE INVENTION

The present invention relates to a toy, and specifically to a toy with a relatively strong interaction.

### BACKGROUND OF THE INVENTION

A traditional toy designed for a baby or a child, such as an animal toy or jigsaw puzzle etc. attracts the child by its appearance. However, it has no interaction with the child.

The improved toy designed for the baby or the child who is learning to walk, such as a baby walker or a push bear etc. enables the child to hold the toy while he/she can learn to walk by means of its novel structural design. However, there is also no interaction between this kind of toy and the baby or the child.

Therefore, it is required to provide a new toy to overcome the problems in the existing toys.

### SUMMARY OF THE INVENTION

The object of the present invention is to provide a toy sensing ball capable of producing a sensing action when a moving object approaches it.

The technical solution for achieving the object of the present invention is to provide a sensing ball, comprising a ball body on which several sensors are mounted, wherein motors, an eccentric device driven by the motor and a controller for controlling rotation of the eccentric device are mounted in the ball body, and wherein the sensors are connected to the controller. When a moving object approaches the sensing ball, the sensors generate sensing signals and input the sensing signals into the controller. The controller controls rotation of the eccentric device and drives the ball body to roll in a specified direction or keeps it static based on the sensing signals.

In particular, the eccentric device comprises a first rotary mechanism rotationally mounted in the ball body, a second rotary mechanism rotationally mounted on the first rotary mechanism and an eccentric counterweight mounted on the second rotary mechanism, wherein the first rotary mechanism drives the ball body to roll back and forth in a first direction and the second rotary mechanism drives the ball body to roll back and forth in a second direction.

Preferably, the sensing ball adopts four sets of sensors which correspond to four directions of rolling of the ball body respectively. The sensors are distributed on the outer surface of the ball body.

Specifically, the specified direction means the direction opposite to the direction of approach of a moving object sensed by the sensors or a third direction when the sensors sense approach of the moving objects from opposite sides. When the sensors sense approach of the moving objects from four directions, the ball body is kept static.

Further, there are provided gravity switches on the ball body, which are used to judge validity of the sensing signals from the sensors, wherein the gravity switches are connected with the electronic signal to the controller, the said gravity switches are installed on the bottom of lower housing when the sensing ball locates in the balanced estate, the gravity switches is turned on when the sensing ball locates in the balanced estate, the sensors can receive the validity of signal.

Preferably, the sensing ball comprises a loudspeaker for playing music, which is connected to the controller.

Specifically, the first rotary mechanism comprises a first motor connected to a power supply, a first set of gears driven by the first motor, a first gear shaft fixed on inner wall of the ball body and a first frame which is driven by the first set of gears and rotates about the first gear shaft. The second rotary mechanism mounted in the first rotary mechanism comprises a second gear shaft mounted on the first frame, a second motor, a second set of gears driven by the second motor and a second frame which is driven by the second set of gears and rotates about the second gear shaft, in which a counterweight for producing eccentric centre is mounted on the second frame.

The present invention also relates to a method for controlling a sensing ball, comprising steps of:

providing the sensing ball on which several sensors are mounted, wherein motors, an eccentric device driven by the motor and a controller for controlling rotation of the eccentric device are mounted, and wherein the sensors are connected to the controller;

generating sensing signals and inputting the sensing signals into the controller when the sensors sense approach of a moving object;

controlling rotation of the eccentric device and driving the sensing ball to roll in a specified direction or keeping it static based on the sensing signals by the controller.

Preferably, there are four sets of sensors mounted on the sensing ball. The specified direction means the direction opposite to the direction of approach of a moving object sensed by the sensors or a third direction when the sensors sense approach of the moving objects from opposite sides. When the sensors sense approach of the moving objects from four directions, the ball body is kept static.

The eccentric device comprises a first rotary mechanism rotationally mounted in the ball body, a second rotary mechanism rotationally mounted on the first rotary mechanism and an eccentric counterweight mounted on the second rotary mechanism, wherein the first rotary mechanism drives the ball body to roll back and forth in a first direction and the second rotary mechanism drives the ball body to roll back and forth in a second direction.

The present invention adopting the above-mentioned technical solutions has the beneficial technical effects as follows: 1) the sensing ball according to the present invention is provided with several sensors thereon, and in the ball body are mounted motors, an eccentric device driven by the motor and a controller for controlling rotation of the eccentric device, in which the sensors are connected to the controller; when a moving object approaches the sensing ball, the sensors generate sensing signals and feed the sensing signals back to the controller; the controller controls rotation of the eccentric device and drives the ball body to roll back and forth in a specified direction or keeps it static based on the sensing signals, thus increasing the interaction between the sensing ball and a person, for example, when a child approaches the sensing ball, the sensing ball can move toward the direction far from the child, therefore stimulating his/her curiosity and attracting him/her to go ahead or creep so that the child may learn to walk and creep in this way; 2) the eccentric device which makes the sensing ball according to the present invention roll back and forth can roll in four directions under the respective actions of the first rotary mechanism and the second mechanism so that the eccentric device can realize automatic rolling in a plurality of directions in a limited space of the sensing ball, that is, its structural design is ingenious; 3) the sensing ball according to the present invention comprises a controller which receives signals from the sensors and drives rotation of the eccentric device based on the signals from the sensors so that the ball body is driven to roll back and forth in the specified direction or kept static, thus realizing the intellectualized movement of the sensing ball; 4) the sensing distance of the sensing ball according to the present invention is in the range of 20 mm to 100 mm.

### BRIEF DESCRIPTION OF THE DRAWINGS

The present invention will be described by means of embodiments, in conjunction with the accompanying drawings, in which:

FIG. 1 is a perspective view of inner structure of a sensing ball according to the present invention when its upper housing is opened;

FIG. 2 is the other perspective view of inner structure of a sensing ball according to the present invention when its upper housing is opened;

FIG. 3 is a perspective view of inner structure of large gear box of a sensing ball according to the present invention;

FIG. 4 is a perspective view of inner structure of small gear box of a sensing ball according to the present invention;

FIG. 5 is a schematic block diagram of a sensing ball according to the present invention;

FIG. 6 is a perspective view of position relations among sensors on a sensing ball according to the present invention.

### DETAILED DESCRIPTION OF THE INVENTION

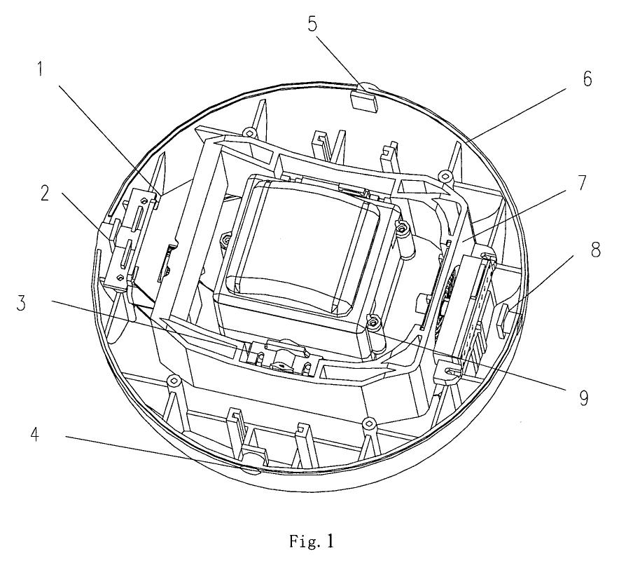

Referring to FIGS. 1 to 6, the present invention relates to a sensing ball, comprising a ball body, several sensors mounted on the ball body, a first motor 17 mounted in the ball body, a second motor 35, an eccentric device and a controller (not shown). In this embodiment, four sets of sensors (2, 4, 8, 5) are adopted.

Referring to FIG. 6, the ball body consists of an upper housing 38 and a lower housing 6. The several sensors (2, 4, 8, 5), the first motor 17, the second motor 35, the eccentric device and the controller are all mounted in the ball body.

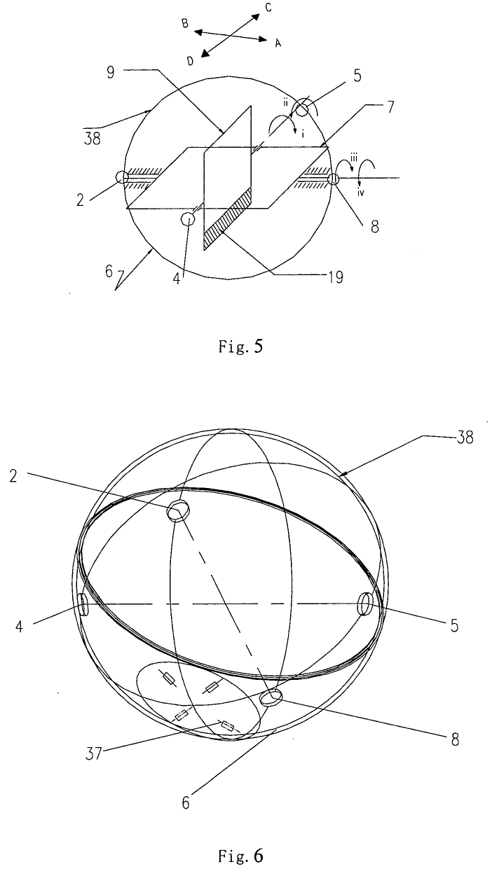

The eccentric device comprises a first rotary mechanism rotationally mounted in the lower housing 6, a second rotary mechanism rotationally mounted on the first rotary mechanism and an eccentric counterweight 19 mounted on the second rotary mechanism. The first rotary mechanism drives the ball body to roll back and forth in a first direction of movement (C-D) and the second rotary mechanism drives the ball body to roll back and forth in a second direction of movement (A-B), as shown in FIG. 5.

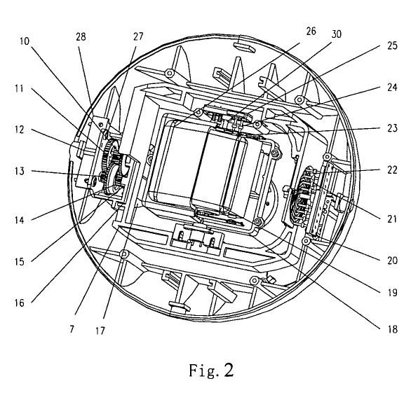

Referring to FIG. 1, FIG. 2 and FIG. 4, the first rotary mechanism comprises a first gear shaft 12, a first frame 7 fixed on the first gear shaft 12, and a small gear box 1 for realizing rotation of the first frame 7. As shown in FIG. 4, the first motor 17 connected to a power supply and a first set of gears driven by the first motor 17 are mounted in the small gear box 1. The first gear shaft 12 is an output of the first set of gears. The first set of gears comprises a crown gear 14, a second gear 10, a third gear 13 and a fourth gear 11, in which the fourth gear 11 is fixedly mounted on the first gear shaft 12.

The gear 15 as an output of the motor is mounted on the first motor 17. The fourth gear 11 is fixedly mounted on the first gear shaft 12. The movement of the first motor 17 is conveyed to the fourth gear 11 through the gear 15, the crown gear 14, the second gear 10 and the third gear 13. Since the fourth gear 11 is fixedly connected to the first gear shaft 12, the movement will be conveyed to the first gear shaft 12. On the other hand, the first gear shaft 12 is fixedly connected with a first pressure plate 28 which in turn is fixedly mounted on the lower housing 6. Therefore, it is impossible to make the first gear shaft 12 rotates with the first motor 17 so that the whole small gear box 1 can only rotate around the fourth gear 11, thus rendering the small gear box 1 to rotate about the first gear shaft 12. Since the small gear box 1 is fixedly mounted on the first frame 7, the first frame 7 can rotate about the first gear shaft 12, that is to say, the first frame 7 can rotate about the first gear shaft 12.

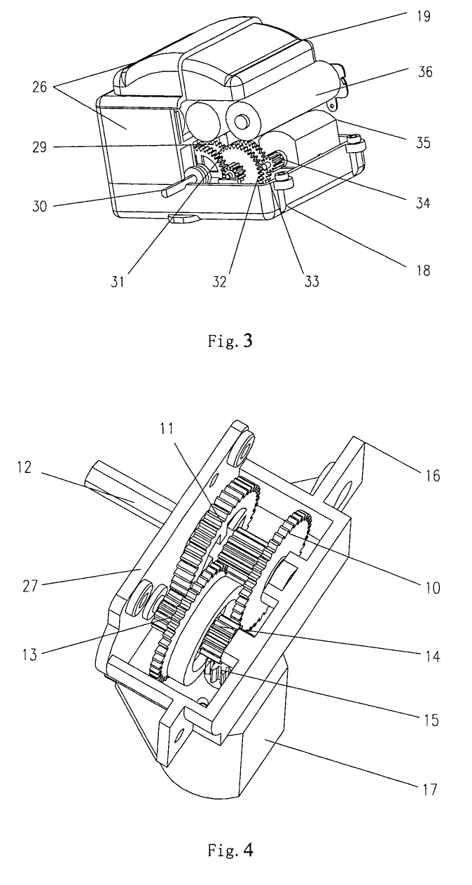

The second rotary mechanism is mounted in the first rotary mechanism, as shown in FIG. 1, FIG. 2 and FIG. 3, and the second rotary mechanism comprises a second gear shaft 30 mounted on the first frame 7, a second frame 26 rotatable on the second gear shaft 30, and a large gear box 9.

Referring to FIG. 3, the large gear box 9 comprises a second motor 35, a second set of gears driven by the second motor 35. The second set of gears comprises a second gear 33, a third gear 29, a fourth gear 32 and a fifth gear 3 1. A counterweight 19 for producing eccentric centre is mounted on the second frame 26.

The fifth gear 31 is fixedly mounted on the second gear shaft 30.Movement of the second motor 35 is conveyed to the fifth gear 31 through the gear 34 mounted on the second motor 35, the second gear 33, the third gear 29 and the fourth gear 32. Therefore, the movement can be conveyed to the second gear shaft 30. At the same time, the second gear shaft 30 is fixedly connected with a second pressure plate 3 which in turn is fixedly mounted on the first frame 7. So, the large gear box 9 can rotate about the second gear shaft 30, that is to say, the second frame 26 can rotate about the second gear shaft 30 mounted on the first frame 7.

Referring to FIG. 2 and FIG. 3, the whole sensing ball is powered by a battery 36. The battery 36 is mounted on the large gear box 9 and the controller (not shown) is mounted on the lower housing 6. The circuits between the first motor 17 of the small gear box 1 mounted on the first frame 7 and the controller (not shown) mounted on the lower housing 6, between the second motor 35 of the large gear box 9 and the first frame 7, i.e. between the rotary part and the fixed part, are connected via conductive plates, thimbles and circuit boards. In particular referring to FIG. 2, the first frame 7 is electrically connected with the lower housing 6 via a first conductive plate 22, a first thimble 21 and a first circuit board 20; the second frame 26 is electrically connected with the first frame 7 via a second conductive plate 23, a second thimble 24 and a second circuit board 25.

Referring to FIG. 6, in this embodiment, four sets of sensors are adopted, comprising a first sensor 2, a second sensor 4, a third sensor 8 and a fourth sensor 5. In the present invention, the optimum sensing distances of the sensors (2, 4, 8, 5) are in the range of 20 mm to 100 mm, that is, when the distance between an object and the sensor (2, 4, 8, 5) is in the range of 20 mm to 100 mm, a signal is received so that the first motor 17 or the second motor 35 is controlled to rotate so as to make the ball body move in a specified direction.

Each of the sensors is connected to the controller. When a moving object approaches the sensing ball, the sensor (2, 4, 8, 5) closest to the object receives a sensing signal indicating that the sensing ball is approached and inputs the sensing signals into the controller. The controller issues an instruction to control positive rotation or reverse rotation of the first motor 17 or the second motor 35 based on the sensing signal, thus rendering the eccentric device to rotate and drive the ball body to roll back and forth in the specified direction or keep it static.

In this embodiment, the four set of sensors correspond to four directions of rolling respectively and control positive rotation or reverse rotation of the first motor 17 and positive rotation or reverse rotation of the second motor 35 separately. The sensors (2, 4, 8, 5) are distributed on the outer surface of the sensing ball, and their functions are to distinguish azimuth from which the object is approaching and then input the sensing signals into the controller, and the controller issues the instruction to the first motor 17 or the second motor 35. So long as the first rotary mechanism and the second rotary mechanism are controlled, and positive rotation or reserve rotation of the motors in the first rotary mechanism and the second rotary mechanism is controlled by the controller, the direction of movement of the sensing ball can be controlled so that the ball can move in the specified direction.

The sensors (2, 4, 8, 5) are used to distinguish the azimuth from which the object is approaching, for example, from what direction a person is approaching the sensing ball. When a certain azimuth sensor receives a signal, it sends the signal to the controller. The controller analyzes from what azimuth the object is approaching the sensing ball and issues the instruction to the motors in the first rotary mechanism and or the second rotary mechanism so as to drive positive rotation or reverse rotation of one of the motors, thus making the sensing ball move in the specified direction and interact with the object.

The sensing ball is required to distinguish the ground due to the sensors; otherwise when the sensing ball rolls or swings in a wide range, it will receive the sensing signals from the ground all the time so that a misjudgment occurs, thus making the sensing ball move all the time.

In order to guarantee accuracy of the signal received by the sensor and reduce possibility of misjudgment, a set of gravity switches 37 is provided on the bottom of the lower housing 6 when the ball locates in the balance estate, the gravity switches 37 is turned on only when the sensing ball locates in the balanced estate, the fourth sets of sensors can receive the validity of signal. When the gravity switches 37 are turned on, the signal of the fourth sets of sensors receives is validity. And the sensing ball will roll for one cycle or its integral multiple, therefore, it can guarantee the bottom of the sensing ball is down before sensing every time, the gravity switches 37 is turned on (located in the reset estate), it can guarantee the validity of signal received by the sensor (2, 4, 8, 5).

Preferably, a loudspeaker for playing music is mounted in the sensing ball, which is connected to the controller.

The concrete sensing procedure is described as follows: when a switch for power supply is turned on, the sensing ball is reset, i.e. ensure two frames of the sensing ball are in the positions shown in FIG. 5. At that time, the bottom of the sensing ball is down, and the gravity switches are turned on, and the sensors can receive and process the sensing signal effectively. When a person approaches the first sensor 2, the first sensor 2 generates a sensing signal and inputs it into the controller. The controller processes the sensing signal and issues the instruction to the second motor 35 in the large gear box 9 to drive positive rotation of the second motor 35, thus driving the large gear box 9 to rotate according to ii direction (seeing FIG. 5, FIG. 3), while the sensing ball move toward A direction, i.e. the direction far from the person.

Similarly, when a person approaches the third sensor 8, the second motor 35 rotates reversely to drive the large gear box 9 to rotate according to i direction (seeing FIG. 5, FIG. 3), while the sensing ball moves toward B direction, i.e. the direction far from the person. When a person approaches the second sensor 4, the controller issues a signal to the first motor 17 in the small gear box to drive positive rotation of the first motor 17, while the large gear box 9 is kept static relative to the first frame 7 and they are mutually perpendicular. So, the first frame 7 along with the large gear box 9 rotates according to iv direction (seeing FIG. 5, FIG. 4) while the sensing ball moves toward C direction. When a person is approaches the fourth sensor 5, the first frame 7 along with the large gear box 9 rotates according to iii direction (seeing FIG. 5, FIG. 4), while the sensing ball moves toward D direction.

Generally speaking, the specified direction means the direction opposite to the direction of approach of a moving object sensed by the sensors or a third direction when the sensors sense approach of the moving objects from opposite sides. When the sensors sense approach of the moving objects from four directions, the ball body is kept static.

The principle of rolling is described with reference to FIG. 5. When the sensing ball interacts with a person, the first frame 7 mounted on the ball body can rotate about its mounting shaft. The second frame 26 mounted on the first frame 7 can also rotate about its mounting shaft. The counterweight 19 is fixedly mounted on the second frame 26.

When the first frame 7 is kept static relative to the ball body, the second frame 26 rotates. The rotation of the second frame 26 can drive the counterweight 19 to rotate together. At that time, the gravity center of the sensing ball will be changed in the plane perpendicular to the rotating shaft of the second frame, and an eccentric force is produced correspondingly in this direction so that the sensing ball moves under the action of the eccentric force. In particular, when the second frame 26 rotates according to i direction as shown, the sensing ball rolls in B direction; and when the second frame 26 rotates according to ii direction, the sensing ball rolls back and forth in A direction.

When the first frame 7 is kept static relative to the second frame 26 and they are in mutually perpendicular positions. When the first frame 7 rotates, it drives the second frame 26 to rotate together. At that time, the gravity center of the sensing ball will be changed in the plane perpendicular to the rotating shaft of the first frame 7, and an eccentric force is produced correspondingly so that the sensing ball moves under the action of the eccentric force. In particular, when the first frame 7 rotates according to iii direction as shown, the sensing ball rolls in D direction; and when the first frame 7 rotates according to iv direction, the sensing ball rolls in C direction.

When two sets of drive systems are used to drive the first frame and the second frame respectively, the sensing ball can move in four directions in horizontal plane through positive rotation and reverse rotation of the two sets of drive systems.

Referring to FIGS. 1 to 6, there is provided a method for controlling a sensing ball, comprising steps of:

providing the sensing ball on which several sensors (2, 4, 8, 5) are mounted, wherein the sensing ball comprises motors (17, 35), an eccentric device driven by the motor and a controller for controlling rotation of the eccentric device, and wherein the sensors are connected to the controller;

generating sensing signals and inputting the sensing signals into the controller when the sensors sense approach of a moving object;

controlling rotation of the eccentric device and driving the sensing ball to roll in a specified direction or keeping it static based on the sensing signals by the controller.

In this embodiment, there are four sets of sensors mounted on the sensing ball. The specified direction means the direction opposite to the direction of approach of a moving object sensed by the sensors or a third direction when the sensors sense approach of the moving objects from opposite sides. When the sensors sense approach of the moving objects from four directions, the ball body is kept static.

The present invention has been described in details by way of above-mentioned specific preferred embodiments, but the embodiments of the present invention are not limited to the description herein. For a person skilled in the art, some simple inference or substitution can be made without departing from the conception of the present invention, which should be within the protective scope of the present invention.

1. A sensing ball, comprising a ball body, characterized in that several sensors are mounted on ball body, wherein motors, an eccentric device driven by the motor and a controller for controlling rotation of the eccentric device are mounted in the ball body, and wherein the sensors are connected to the controller; when a moving object approaches the sensing ball, the sensors generate sensing signals and input the sensing signals into the controller; the controller controls rotation of the eccentric device and drives the ball body to roll in a specified direction or keeps it static based on the sensing signals.

2. The sensing ball according to claim 1, characterized in that the eccentric device comprises a first rotary mechanism rotationally mounted in the ball body, a second rotary mechanism rotationally mounted on the first rotary mechanism and an eccentric counterweight mounted on the second rotary mechanism, wherein the first rotary mechanism drives the ball body to roll back and forth in a first direction and the second rotary mechanism drives the ball body to roll back and forth in a second direction.

3. The sensing ball according to claim 2, characterized in that the sensing ball adopts four sets of sensors which correspond to four directions of rolling of the ball body respectively, wherein the sensors are distributed on outer surface of the ball body.

4. The sensing ball according to claim 2, characterized in that the specified direction means the direction opposite to the direction of approach of a moving object sensed by the sensors or a third direction when the sensors sense approach of the moving objects from opposite sides, and when the sensors sense approach of the moving objects from four directions, the ball body is kept static.

5. The sensing ball according to claims 2, characterized in that there are provided gravity switches on the ball body, which are used to judge validity of the sensing signals from the sensors, wherein the gravity switches are connected with the electronic signal to the controller, the said gravity switches are installed on the bottom of lower housing when the sensing ball locates in the balanced estate, the gravity switches is turned on when the sensing ball locates in the balanced estate, the sensors can receive the validity of signal.

6. The sensing ball according to claims 3, characterized in that there are provided gravity switches on the ball body, which are used to judge validity of the sensing signals from the sensors, wherein the gravity switches are connected with the electronic signal to the controller, the said gravity switches are installed on the bottom of lower housing when the sensing ball locates in the balanced estate, the gravity switches is turned on when the sensing ball locates in the balanced estate, the sensors can receive the validity of signal.

7. The sensing ball according to claims 4, characterized in that there are provided gravity switches on the ball body, which are used to judge validity of the sensing signals from the sensors, wherein the gravity switches are connected with the electronic signal to the controller, the said gravity switches are installed on the bottom of lower housing when the sensing ball locates in the balanced estate, the gravity switches is turned on when the sensing ball locates in the balanced estate, the sensors can receive the validity of signal.

8. The sensing ball according to claim 5, characterized in that the sensing ball comprises a loudspeaker for playing music, which is connected to the controller.

9. The sensing ball according to claim 2, characterized in that the first rotary mechanism comprises a first motor connected to a power supply,—a first set of gears driven by the first motor, a first gear shaft fixed on inner wall of the ball body and a first frame which is driven by the first set of gears and rotates about the first gear shaft, wherein the second rotary mechanism mounted in the first rotary mechanism comprises a second gear shaft mounted on the first frame, a second motor, a second set of gears driven by the second motor and a second frame which is driven by the second set of gears and rotates about the second gear shaft, in which a counterweight for producing eccentric centre is mounted on the second frame.

10. The sensing ball according to claim 3, characterized in that the first rotary mechanism comprises a first motor corrected to a power supply,—a first set of gears driven by the first motor, a first gear shaft fixed on inner wall of the ball body and a first frame which is driven by the first set of gears and rotates about the first gear shaft, wherein the second rotary mechanism mounted in the first rotary mechanism comprises a second gear shaft mounted on the first frame, a second motor, a second set of gears driven by the second motor and a second frame which is driven by the second set of gears and rotates about the second gear shaft, in which a counterweight for producing eccentric centre is mounted on the second frame.

11. The sensing ball according to claim 4, characterized in that the first rotary mechanism comprises a first motor corrected to a power supply,—a first set of gears driven by the first motor, a first gear shaft fixed on inner wall of the ball body and a first frame which is driven by the first set of gears and rotates about the first gear shaft, wherein the second rotary mechanism mounted in the first rotary mechanism comprises a second gear shaft mounted on the first frame, a second motor, a second set of gears driven by the second motor and a second frame which is driven by the second set of gears and rotates about the second gear shaft, in which a counterweight for producing eccentric centre is mounted on the second frame.

12. The sensing ball according to claim 5, characterized in that the first rotary mechanism comprises a first motor corrected to a power supply,—a first set of gears driven by the first motor, a first gear shaft fixed on inner wall of the ball body and a first frame which is driven by the first set of gears and rotates about the first gear shaft, wherein the second rotary mechanism mounted in the first rotary mechanism comprises a second gear shaft mounted on the first frame, a second motor, a second set of gears driven by the second motor and a second frame which is driven by the second set of gears and rotates about the second gear shaft, in which a counterweight for producing eccentric centre is mounted on the second frame.

13. The sensing ball according to claim 6, characterized in that the first rotary mechanism comprises a first motor corrected to a power supply,—a first set of gears driven by the first motor, a first gear shaft fixed on inner wall of the ball body and a first frame which is driven by the first set of gears and rotates about the first gear shaft, wherein the second rotary mechanism mounted in the first rotary mechanism comprises a second gear shaft mounted on the first frame, a second motor, a second set of gears driven by the second motor and a second frame which is driven by the second set of gears and rotates about the second gear shaft, in which a counterweight for producing eccentric centre is mounted on the second frame.

14. A method for controlling a sensing ball, characterized in that the method comprises steps of:
providing the sensing ball on which several sensors are mounted, wherein motors, an eccentric device driven by the motor and a controller for controlling rotation of the eccentric device are mounted, and wherein the sensors are connected to the controller;
generating sensing signals and inputting the sensing signals into the controller when the sensors sense approach of a moving object;
controlling rotation of the eccentric device and driving the sensing ball to roll in a specified direction or keeping it static based on the sensing signals by the controller.

15. The method for controlling a sensing ball according to claim 14, characterized in that there are four sets of sensors mounted on the sensing ball, wherein the specified direction means the direction opposite to the direction of approach of a moving object sensed by the sensors or a third direction when the sensors sense approach of the moving objects from opposite sides, and when the sensors sense approach of the moving objects from four directions, the ball body is kept static.

16. The method for controlling a sensing ball according to claim 15, characterized in that the eccentric device comprises a first rotary mechanism rotationally mounted in the ball body, a second rotary mechanism rotationally mounted on the first rotary mechanism and an eccentric counterweight mounted on the second rotary mechanism, wherein the first rotary mechanism drives the ball body to roll back and forth in a first direction and the second rotary mechanism drives the ball body to roll back and forth in a second direction.
